(19) United States
(12) Patent Application Publication
(10) Pub. No.: US 2013/0341640 A1
(43) Pub. Date: Dec. 26, 2013

(54) SEMICONDUCTOR DEVICE AND METHOD FOR MANUFACTURING SAME

(71) Applicant: Hiroyuki Sakurai, Tokyo (JP)

(72) Inventor: Hiroyuki Sakurai, Tokyo (JP)

(21) Appl. No.: 13/728,029

(22) Filed: Dec. 27, 2012

(30) Foreign Application Priority Data
Jun. 20, 2012 (JP) 2012-138976

(51) Int. Cl. H01L 29/40

(52) U.S. Cl. CPC H01L 29/402; H01L 29/401
USPC 257/77; 438/172

(57) ABSTRACT

According to an embodiment, a semiconductor device includes a semiconductor, a source electrode, a drain electrode, an insulating layer and a gate electrode. The semiconductor layer includes an GaN layer and a AlGaN layer provided on the GaN layer. The source electrode and the drain electrode are provided on the semiconductor layer. The insulating layer is provided on the semiconductor layer between the source electrode and the drain electrode. The gate electrode includes a penetrating portion and a gate field plate, the penetrating portion being in contact with the semiconductor layer through the insulating layer and containing platinum in contact with the semiconductor layer, the gate field plate being in contact with an upper face of the insulating layer with a contact length of not less than 0.1 micrometers and not more than 0.3 micrometers and containing platinum in contact with the upper surface.

### CROSS-REFERENCE TO RELATED APPLICATIONS

This application is based upon and claims the benefit of priority from Japanese Patent Application No. 2012-138976, filed on Jun. 20, 2012; the entire contents of which are incorporated herein by reference.

### FIELD

Embodiments are generally related to a semiconductor device and a method for manufacturing the same.

### BACKGROUND

The electric field concentration in the drain-side of the gate electrode, for example, may reduce the breakdown voltage or cause the current collapse phenomenon in a semiconductor device. In view of this, a gate field plate is formed in connection with the gate electrode in order to mitigate the electric field concentration. However, inappropriate shape of the gate field plate, particularly the gate field plate length, will adversely affect the electrical characteristics of the semiconductor device.

### BRIEF DESCRIPTION OF THE DRAWINGS

FIG. 1 is a cross-sectional view illustrating a semiconductor device according to a first embodiment;

FIGS. 2A to 3C are schematic cross-sectional views illustrating a manufacturing method of the semiconductor device according to the first embodiment;

FIG. 4 is a cross-sectional view illustrating a semiconductor device according to a first comparative example of the first embodiment;

FIGS. 5A to 6B are schematic cross-sectional views illustrating a manufacturing method of the semiconductor device according to the first comparative example of the first embodiment;

FIG. 7 is a cross-sectional view illustrating a semiconductor device according to a second comparative example of the first embodiment;

FIGS. 8A to 8C are schematic cross-sectional views illustrating a manufacturing method of a semiconductor device according to the second comparative example of the first embodiment;

FIG. 9 is a cross-sectional view illustrating a semiconductor device according to a second embodiment; and

FIG. 10 is a schematic cross-sectional view illustrating a manufacturing method of the semiconductor device according to the second embodiment.

### DETAILED DESCRIPTION

According to an embodiment, a semiconductor device includes a semiconductor, a source electrode, a drain electrode, an insulating layer and a gate electrode. The semiconductor layer includes a GaN layer and an AlGaN layer provided on the GaN layer. The source electrode and the drain electrode are provided on the semiconductor layer. The insulating layer is provided on the semiconductor layer between the source electrode and the drain electrode. The gate electrode includes a penetrating portion and a gate field plate, the penetrating portion being in contact with the semiconductor layer through the insulating layer and containing platinum in contact with the semiconductor layer, the gate field plate being in contact with an upper face of the insulating layer with a contact length of not less than 0.1 micrometers and not more than 0.3 micrometers and containing platinum in contact with the upper surface.

Hereinbelow, embodiments of the invention are described with reference to the drawings.

### First Embodiment

A first embodiment is described.

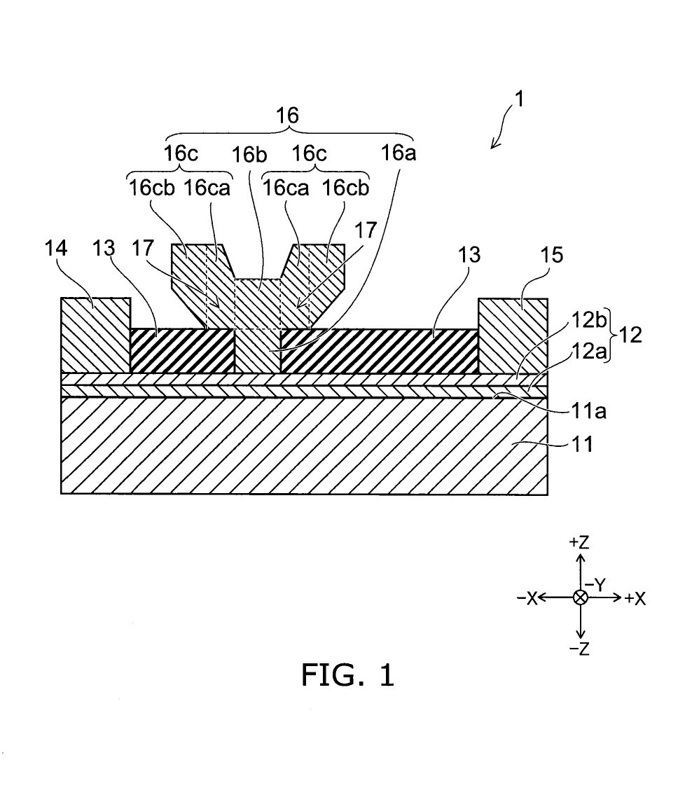

FIG. 1 is a cross-sectional view illustrating a semiconductor device according to a first embodiment.

As shown in FIG. 1, a semiconductor device 1 according to the embodiment includes a semiconductor layer 12 provided on a substrate 11, an insulating layer 13, a source electrode 14, a drain electrode 15, and a gate electrode 16. The substrate 11 is, for example, a silicon carbide (SiC) substrate.

The substrate 11 may be removed after the semiconductor layer 12 is formed. Alternatively, the first substrate may be removed and a second substrate different from the first substrate may be attached to the semiconductor layer 12.

The semiconductor layer 12 includes, for example, a GaN (gallium nitride) layer 12a in its lower portion and an AlGaN (aluminum gallium nitride) layer 12b in its upper portion.

Hereinafter, the semiconductor device 1 is described referring to XYZ orthogonal coordinate system. In the XYZ orthogonal coordinate system, one direction is defined as +X direction, and the direction opposite to the +X direction is defined as −X direction in a plane parallel to the upper surface 11a of the substrate 11. One direction orthogonal to the +X direction is defined as +Y direction, and the direction opposite to the +Y direction is defined as −Y direction in the plane parallel to the upper surface 11a of the substrate 11. One direction orthogonal to both the +X direction and the +Y direction is defined as +Z direction, and the direction opposite to the +Z direction is defined as the −Z direction. The “+X direction” and the “−X direction” may be collectively referred to as the “X direction.” The “+Y direction” and the “−Y direction” may be collectively referred to as the “Y direction.” The “+Z direction” and the “−Z direction” may be collectively referred to as the “Z direction.”

The source electrode 14 is provided on the semiconductor layer 12. The source electrode 14 extends in the Y direction, for example. The source electrode 14 contains, for example, a metal.

The drain electrode 15 is provided on the semiconductor layer 12 away from the source electrode 14 in the X direction. The drain electrode 15 extends in the Y direction, for example. The drain electrode 15 contains, for example, a metal.

The insulating layer 13 is provided on the semiconductor layer 12 between the source electrode 14 and the drain electrode 15. The insulating layer 13 contains, for example, silicon nitride (SiN). The insulating layer 13 has a thickness of 0.1 μm, for example.

The gate electrode 16 penetrating through the insulating layer 13 is provided on the semiconductor layer 12 between the source electrode 14 and the drain electrode 15. The gate electrode 16 extends in the Y direction, for example. The cross section in the XZ plane of the gate electrode 16 has a Y-shape. That is, the gate electrode 16 includes a portion 16a penetrating through the insulating film 13, a portion 16b provided immediately above the penetrating portion 16a, and side portions 16c extending from the portion 16b in the +X direction and the −X direction.

The lower face of the penetrating portion 16a is in contact with the AlGaN layer 12b. The width in the X direction of the lower face of the penetrating portion 16a is the gate length. The gate length is not less than 0.1 μm and not more than 0.5 μm; for example, it is 0.1 μm. The upper surface of the penetrating portion 16a locates at the same level as the upper surface of the insulating layer 13. The side surface of the penetrating portion 16a is in contact with the insulating layer 13. The portion 16b is provided on the upper surface of the penetrating portion 16a.

The upper end of the side portion 16c locates higher than the upper end of the portion 16b, for example. The lower face of the side portion 16c includes a portion in contact with the upper face of the insulating layer 13. The portion of the side portion 16c in contact with the upper surface of the insulating layer 13 is referred to as a gate field plate 17. The width in the X direction of the gate field plates 17, for example, the length between one end edge on the penetrating portion 16a side and the end edge on the source electrode 14 side is referred to as a gate field plate length. The width of the gate field plate 17 between another end edge on the penetrating portion 16a side and the end edge on the drain electrode 15 side is also referred to as a gate field plate length. The gate field plate length is not less than 0.1 micrometers (μm) and not more than 0.3 (μm); for example, it is 0.1 (μm). The gate field length on the source electrode 14 side and the gate field length on the drain electrode 15 side are, for example, set to the same length.

The side portions 16c include portions 16ca that are the gate field plates 17 on the source electrode 14 side and the drain electrode 15 side, a portion 16cb that extends toward the source electrode 14 from the gate field plate 17, and a portion 16cb that extends toward the drain electrode 15 from the gate field plate 17. The length in the X direction of the portion 16cb on the source electrode 14 side is preferably shorter than the length in the X direction of the portion 16cb on the drain electrode 15 side.

The lower face of the portion 16cb is away from the insulating layer 13 in the Z direction. The distance between the portion 16cb and the upper face of the insulating layer 13 increases with distance from the gate field plate 17.

The lower portion of the gate electrode 16 contains nickel (Ni). The portion 16a of the gate electrode 16 forms a Schottky junction with the AlGaN layer 12b. The upper portion of the gate electrode 16 contains gold (Au).

Next, an operation of the semiconductor device according to the embodiment is described.

In the semiconductor device 1, the heterojunction of the AlGaN layer 12b and the GaN layer 12a induces two-dimensional electron gas near the heterointerface on the GaN layer 12a side, where electrons generated in the AlGaN layer 12b move to the GaN layer 12a. Owing to small impurity scattering in the undoped GaN layer 12a, the two-dimensional electron gas exhibits high electron mobility.

The source electrode 14 and the drain electrode 15 are formed so as to obtain ohmic contact with the AlGaN layer 12b. By applying a voltage between the source electrode 14 and the drain electrode 15, a current flows through the two-dimensional electron gas from the drain electrode 15 to the source electrode 14. The gate electrode 16 is in contact with the surface of the AlGaN layer 12b, forming a Schottky junction. The two depletion regions are formed in the AlGaN layer 12b. One is a depletion region extending from the Schottky junction, and the other is a depletion region induced by the electron move that forms the two-dimensional electron gas and extending from the heterointerface side.

The thickness of the AlGaN layer 12b is selected so that the two depletion regions are merged into one region, and a voltage applied to the gate electrode 16 changes the width of the merged depletion region. Thus, the gate voltage may change the concentration of the two-dimensional electron through the electric field effect, and controls the opening and closing of the current path between the drain electrode and the source electrode.

The gate field plate 17 may mitigate the electric field concentration at the end edges of the portion 16a of the gate electrode 16.

Next, a method for manufacturing a semiconductor device according to the embodiment is described.

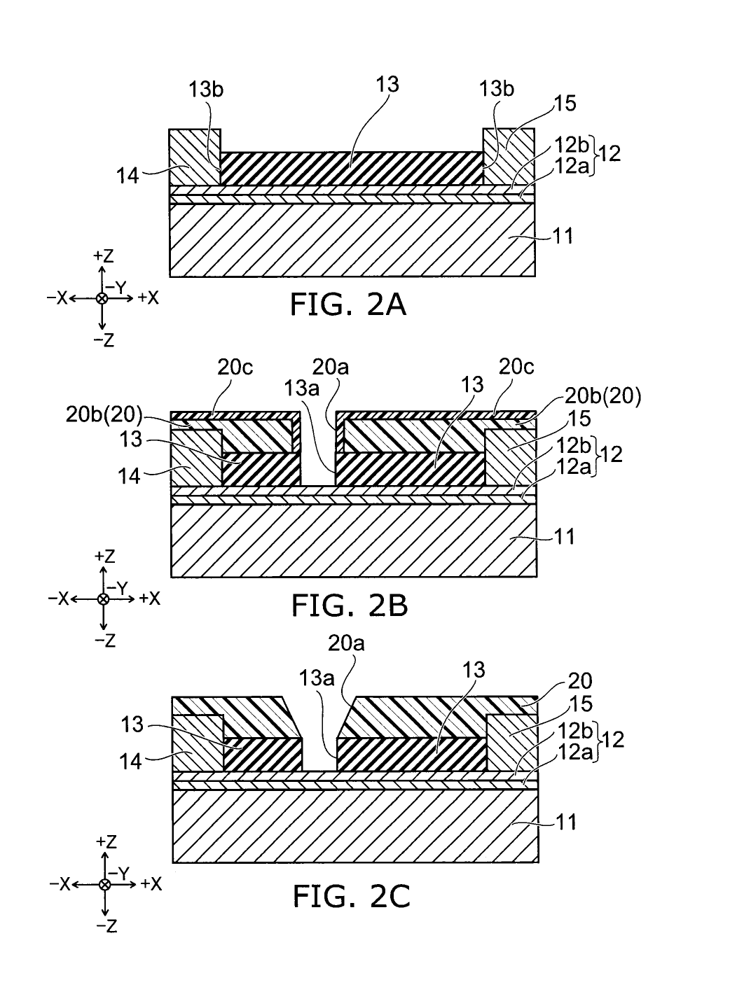

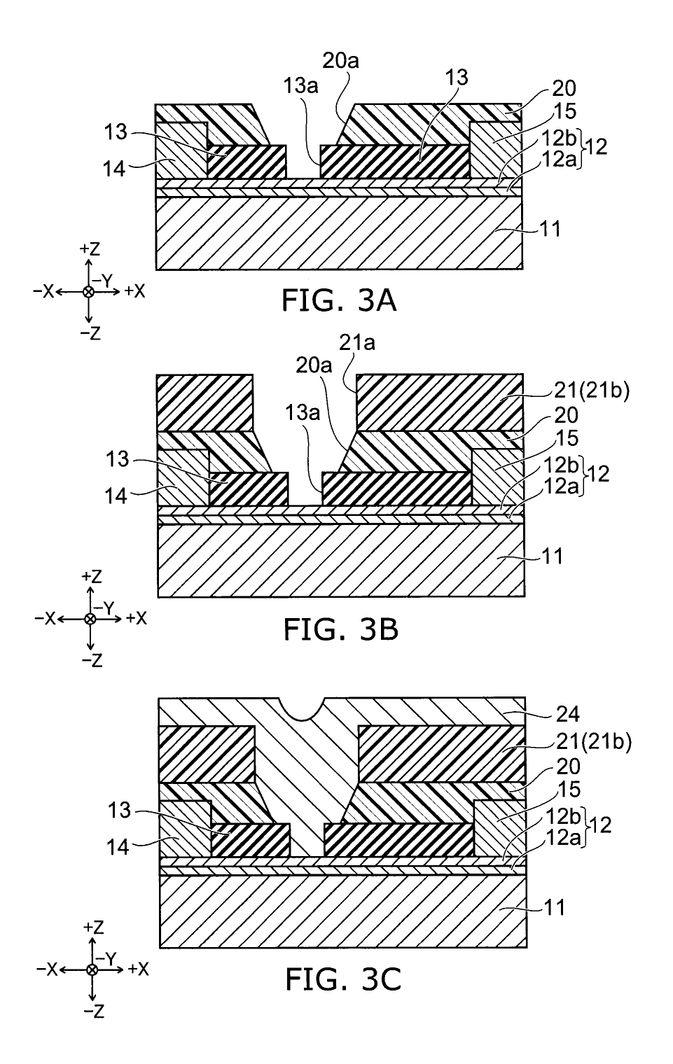

FIGS. 2A to 3C are schematic cross-sectional views illustrating a manufacturing process of the semiconductor device 1 according to the embodiment.

First, the substrate 11, for example, a silicon carbide (SiC) substrate is prepared. Next, the GaN layer 12a is formed on the substrate 11 by epitaxial growth. Then, the AlGaN layer 12b is formed on the GaN layer 12a by epitaxial growth. After that, the insulating layer 13 containing silicon nitride is formed with a thickness of 0.1 μm on the AlGaN layer 12b, for example. Then, a plurality of openings 13b penetrating through the insulating layer 13 are formed in order to bury the source electrode 14 and the drain electrode 15 in the insulating layer 13. The openings 13b extend in the Y direction, for example. The openings 13b are formed so as to be away from one another in the X direction in the insulating layer 13. After that, a metal film is buried in the openings 13b, and portions other than the openings 13b of the metal film are removed so as to form the source electrode 14 and the drain electrode 15, as shown in FIG. 2A.

Next, a photoresist film 20 is formed on the insulating layer 13. Then, using the photolithography, a photoresist pattern 20b including an opening 20a is formed on the photoresist film 20. After that, the photoresist pattern 20b is used as a mask to perform, for example, dry etching using a SF₆-based gas to transfer the photoresist pattern 20b to the insulating layer 13. Thereby, an opening 13a is formed in the insulating layer 13 as shown in FIG. 2B. The length in the X direction of the opening 13a serves as the gate length. In the dry etching, for example, the upper portion of the photoresist film 20 and the side surface of the opening 20a are altered into a cured layer 20c, for example.

Next, heat treatment is performed by, for example, through a reflow process. Thereby, the cured layer 20c is fluidized, and the upper portion of the opening 20a in the photoresist film 20 expands to be a tapered shape as shown in FIG. 2C. Thus, by controlling the conditions of dry etching and heat treatment conditions, the shape of the opening 20a in the photoresist film 20 may be changed so that the inner diameter of the opening 20a is largest at the upper face and decreases downward. The inner diameter of the opening 20a at the lower face of the photoresist film 20 is maintained to be equal to the inner diameter of the opening 13a in the insulating layer 13.

Next, as shown in FIG. 3A, for example, isotropic etching-back is performed by plasma treatment using oxygen to remove a surface portion of the photoresist film 20. The inner diameter of the opening 20a in the photoresist film 20 becomes larger with the tapered shape. Therefore, the inner diameter of the opening 20a at the lower face of the photoresist film 20 becomes larger than the inner diameter of the opening 13a of the insulating layer 13. Thereby, the upper face of the insulating layer 13 is exposed at the bottom of the opening 20a. The length in the X direction of the upper face of the insulating layer 13 exposed at the bottom the opening 20a can be controlled by the conditions of plasma treatment, such as the treatment time, for example.

Furthermore, etching residues and defects formed at the surface of the photoresist film 20 are removed while the plasma treatment. The etched surface becomes hydrophilic, thereby it becomes possible to facilitate washing with pure water or chemical agent. Moreover, the adhesion of a photoresist film formed thereon is improved.

Next, as shown in FIG. 3B, a photoresist film 21 is formed on the photoresist film 20. Then, a photoresist pattern 21b is formed on the photoresist film 21. The photoresist pattern 21b includes an opening 21a formed by removing a portion immediately above the opening 20a. The total thickness of the photoresist film 20 and the photoresist film 21 is made 0.8 μm to 1 μm. After that, for example, isotropic etching-back is performed by plasma treatment using oxygen to remove the upper surface of the photoresist film 21 and the side surfaces of the opening 20a and the opening 21a. Thereby, etching residues and defects formed at the upper face of the photoresist film 21 and the side faces of the opening 20a and the opening 21a are removed. Also resist residues of the photoresist film 20 and the photoresist film 21 in the opening 13a are removed. Further, the upper face of the semiconductor layer 12 is planarized. At this time, the length in the X direction of the upper face of the insulating layer 13 exposed at the bottom surface of the opening 20a can be controlled by the conditions of plasma treatment, such as the treatment time, for example.

Next, as shown in FIG. 3C, a nickel (Ni) film, for example, is formed by the vacuum evaporation method so that the nickel (Ni) film is buried in the opening 13a, the opening 20a, and the opening 21a and is in contact with the AlGaN layer 12b. The nickel (Ni) film forms a Schottky junction with the AlGaN layer. A gold (Au) film is formed on the nickel (Ni) film. The gold (Au) film reduces the resistance of the gate electrode. Thereby, a metal film 24 is formed filling the opening 13a, the opening 20a, and the opening 21a. The metal film 24 includes the nickel (Ni) film in its lower portion and the gold (Au) film in its upper portion. The thickness of the metal film 24 is set to 0.5 μm. After that, portions of the metal film 24 provided on the upper face of the photoresist film 21 are removed together with the photoresist film 20 and the photoresist film 21.

Thus, the semiconductor device 1 like that shown in FIG. 1 is manufactured. Next, effects of the embodiment are described.

In the embodiment, the gate electrode 16 of the semiconductor device 1 includes the gate field plate 17. The gate field plate may mitigate the electric field concentration in the end portion of the gate electrode 16, and thereby improving the breakdown voltage. Furthermore, it is possible to suppress the current collapse.

The gate field plate length is 0.1 micrometers (μm) or more, and the gate field plate 17 is in contact with the gate insulating layer 13. Thereby, the gate field plate may improve the adhesion strength between the gate electrode 16 and the AlGaN layer 12b. Furthermore, since the gate field plate length is 0.3 micrometers (μm) or less, the parasitic capacitance can be kept low. The parasitic capacitance adversely affects the movement of electrons at high frequencies. Hence, electrical characteristics can be improved by reducing the parasitic capacitance in the semiconductor device 1. In particular, the length of the gate field plate 17 is preferably set to be 0.3 micrometers (μm) or less for the application in high frequency range such as 14 GHz or more. The gate field plate length is also set in this range for suppressing the current collapse.

In the case where the distance between the penetrating portion 16a of the gate electrode 16 and the source electrode 14 is set to 0.7 micrometers (μm), for example, and the gate field plate length is larger than 0.3 micrometers (μm), it may be necessary to add an extra process for insulating therebetween. Because the distance between the side portion 16c of the Y-shaped gate electrode 16 and the source electrode 14 is narrowed. However, when the gate field plate length is 0.3 micrometers (μm) or less, no additional process is needed. When the length of the extending portion 16cb on the source electrode 14 side is made shorter than the length of the extending portion 16cb on the drain electrode 15 side, it becomes easy to keep the insulation between the side portion 16c and the source electrode 14.

The gate electrode 16 includes the side portion 16c. Thereby, the cross-sectional area in the XZ plane of the gate electrode 16 increases and it is possible to reduce the electric resistance of the gate electrode 16. Furthermore, the gate electrode 16 includes the extending portion 16cb. Thereby, high frequency characteristics can be improved and electric field concentration can be mitigated.

The upper face of the semiconductor layer 12 exposed at the opening 13a can be planarized while the plasma treatment using oxygen. Thereby, it is possible to improve the adhesiveness in the Schottky junction.

Although a silicon carbide (SiC) substrate is used as the substrate 11, the substrate 11 is not limited thereto in the embodiment. A silicon (Si) substrate is also possible, for example. Also a substrate may be used in which a silicon carbide layer is provided on a silicon substrate. As mentioned above, the insulating layer 13 contains silicon nitride (SiN), but the insulating layer 13 is not limited thereto. The insulating layer 13 may contain silicon oxide (SiO₂). The metal film is not only formed by the vacuum evaporation method, but the metal film may also be formed by a sputtering method.

### COMPARATIVE EXAMPLES

Next, a first comparative example of the first embodiment is described.

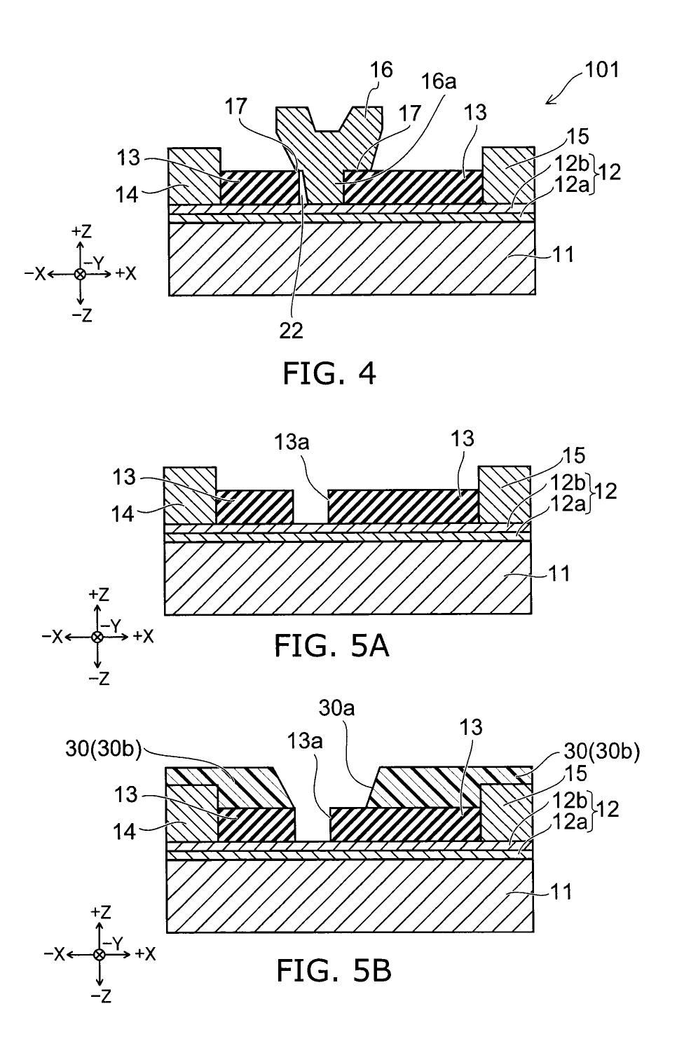

FIG. 4 is a cross-sectional view illustrating a semiconductor device according to the first comparative example of the first embodiment.

As shown in FIG. 4, in a semiconductor device 101 according to the comparative example, the gate field plate length on the source electrode 14 side is smaller than the gate field plate length on the drain electrode 15 side. A space 22 is formed between the portion 16a of the gate electrode 16 and the insulating layer 13. That is, the side face of the portion 16a on the source electrode side is not in contact with the insulating layer 13.

Next, a manufacturing method of the semiconductor device 101 is described according to the comparative example.

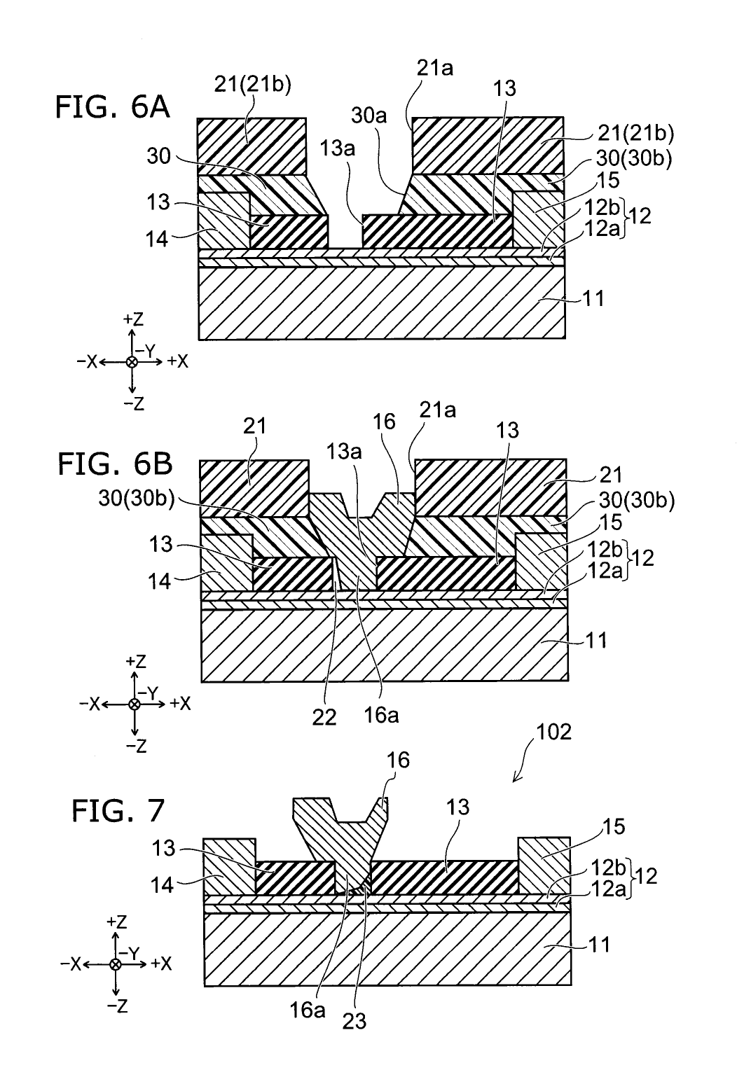

FIGS. 5A to 6B are schematic cross-sectional views illustrating a manufacturing process of the semiconductor device 101.

First, similarly to the first embodiment described above, the processes shown in FIGS. 2A and 2B are performed. A description of these processes is omitted.

FIG. 5A is a schematic cross-sectional view illustrating a part of substrate 11, after removing the photoresist film 20 (see FIG. 2B), on which the semiconductor layer 12, the insulating layer 13, the source electrode 14 and drain electrode 15 are provided.

Next, as shown in FIG. 5B, a photoresist film 30 is formed on the insulating layer 13. Then, the photoresist film 30 is patterned to form a photoresist pattern 30b including an opening 30a. The opening 30a is formed so as to include a region immediately above the opening 13a. However, due to misalignment of patterning, the center of the opening 30a is shifted to the +X direction side with respect to the center of the opening 13a.

Next, as shown in FIG. 6A, the photoresist film 21 is formed on the photoresist film 30. Then, the photoresist pattern 21b is formed on the photoresist film 21. The photoresist pattern 21b includes the opening 21a formed by removing a portion immediately above the opening 30a.

Next, as shown in FIG. 6B, a nickel (Ni) film, for example, is formed by the vacuum evaporation method, so that the nickel (Ni) film is buried in the opening 13a, the opening 30a, and the opening 21a and is in contact with the AlGaN layer 12b. A gold (Au) film is formed on the nickel (Ni) film. After that, of the nickel (Ni) film and the gold (Au) film portions provided on the upper face of the photoresist film 21 are removed. After that, the photoresist film 30 and the photoresist film 21 are removed.

Thus, the semiconductor device 101 is manufactured as shown in FIG. 4.

In the semiconductor device 101 in the comparative example, since misalignment has occurred between the center of the opening 30a and the center of the opening 13a, the gate field plate length on the source electrode 14 side is formed to be smaller than a prescribed length. Consequently, the electric field concentration in the end portion of the gate electrode 16 cannot be mitigated on the source electrode 14 side, and it may not be enough to suppress the current collapse.

Furthermore, since the gate field plate length is formed to be small, the adhesion strength may be reduced between the insulating layer 13 and the gate electrode 16.

Moreover, in the semiconductor device 101, the space 22 is formed on the source electrode 14 side of the gate electrode 16 between the penetrating portion 16a and the insulating layer 13. Therefore, the gate length becomes short, and the width of Schottky junction also becomes small. Consequently, the misalignment of the opening 30a in the photoresist film 30 may cause the degradations in the electrical characteristics of the semiconductor device 101.

Next, a second comparative example of the first embodiment is described.

FIG. 7 is a cross-sectional view illustrating a semiconductor device according to the second comparative example of the first embodiment.

As shown in FIG. 7, in a semiconductor device 102 according to the comparative example, a resist residue 23 remains between the gate electrode 16 and the AlGaN layer 12b and between the penetrating portion 16a and the insulating layer 13 on the drain electrode 15 side. The gate field plate length on the drain electrode 15 side is smaller than the gate field plate length on the source electrode 14 side, and is not formed to be a prescribed length.

Next, a manufacturing method for the semiconductor device 102 according to the comparative example is described.

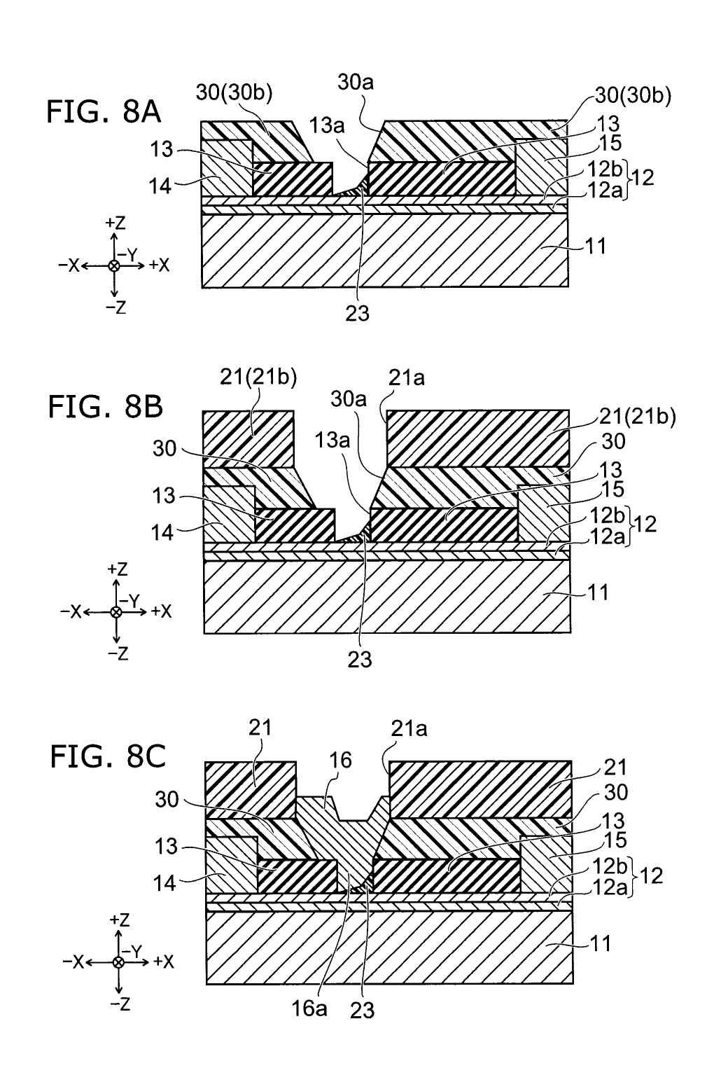

FIGS. 8A to 8C are schematic cross-sectional views illustrating a manufacturing process of the semiconductor device according to the second comparative example of the first embodiment.

First, similarly to the first embodiment described above, the processes shown in FIGS. 2A and 2B are performed. Next, similarly to the first comparative example described above, the process shown in FIG. 5A is performed. The descriptions of these processes are omitted.

FIG. 8A is a schematic cross-sectional view illustrating a part of substrate 11 on which the semiconductor layer 12, the insulating layer 13, the source electrode 14 and drain electrode 15 are provided.

As shown in FIG. 8A, the photoresist film 30 is formed on the insulating layer 13. Then, the photoresist film 30 is patterned to form the photoresist pattern 30b including the opening 30a. The opening 30a is formed so as to include a region immediately above the opening 13a. However, due to misalignment of patterning, the center of the opening 30a is shifted to the −X direction side with respect to the center of the opening 13a. The resist residue 23 remains on the AlGaN layer 12b exposed at the bottom of the opening 13a.

Next, as shown in FIG. 8B, the photoresist film 21 is formed on the photoresist film 30. Then, the photoresist pattern 21b is formed on the photoresist film 21. The photoresist pattern 21b includes the opening 21a formed by removing a portion immediately above the opening 30a. At this time, the resist residue 23 still remains on the bottom of the opening 13a.

Next, as shown in FIG. 8C, a nickel (Ni) film, for example, is formed by the vacuum evaporation method, so that the nickel (Ni) film is buried in the opening 13a, the opening 30a, and the opening 21a and is in contact with the AlGaN layer 12b. A gold (Au) film is formed on the nickel (Ni) film. After that, portions on the upper surface of the photoresist film 21 of the nickel (Ni) film and the gold (Au) film are removed. After that, the photoresist film 30 and the photoresist film 21 are removed.

Thus, the semiconductor device 102 is manufactured as shown in FIG. 7.

Also in the semiconductor device 102 in the comparative example, since misalignment has occurred between the center of the opening 30a and the center of the opening 13a, the gate field plate length on the drain electrode 15 side is formed to be smaller than a prescribed length. Therefore, the electric field concentration in the end portion of the gate electrode 16 cannot be mitigated on the drain electrode 15 side, and it may also be not enough to suppress the current collapse. Consequently, it may not be sufficient to improve the electrical characteristics of the semiconductor device 102.

Furthermore, in the semiconductor device 102, the resist residue 23 remains between the gate electrode 16 and the AlGaN layer 12b and between the penetrating portion 16a and the insulating layer 13 on the drain electrode 15 side. Accordingly, the gate electrode 16 may float above the upper face of the AlGaN layer 12b, causing a bad contact therebetween. Therefore, it may also deteriorate the electrical characteristics of the semiconductor 102.

As explained above referring to the first and the second comparative example, misalignment may occur in the fine alignment process for forming the gate field plate 17 with small length, and negatively affect the characteristics of the semiconductor device. In contrast to this, the opening 13a in the insulating film 13 and the opening 20a in the photoresist pattern 20b are formed in the self-aligned process. Accordingly, in the embodiment, there is no misalignment, and it is possible to stably form the gate field plate 17 with small length, and to improve the device characteristics.

### Second Embodiment

Next, a second embodiment is described.

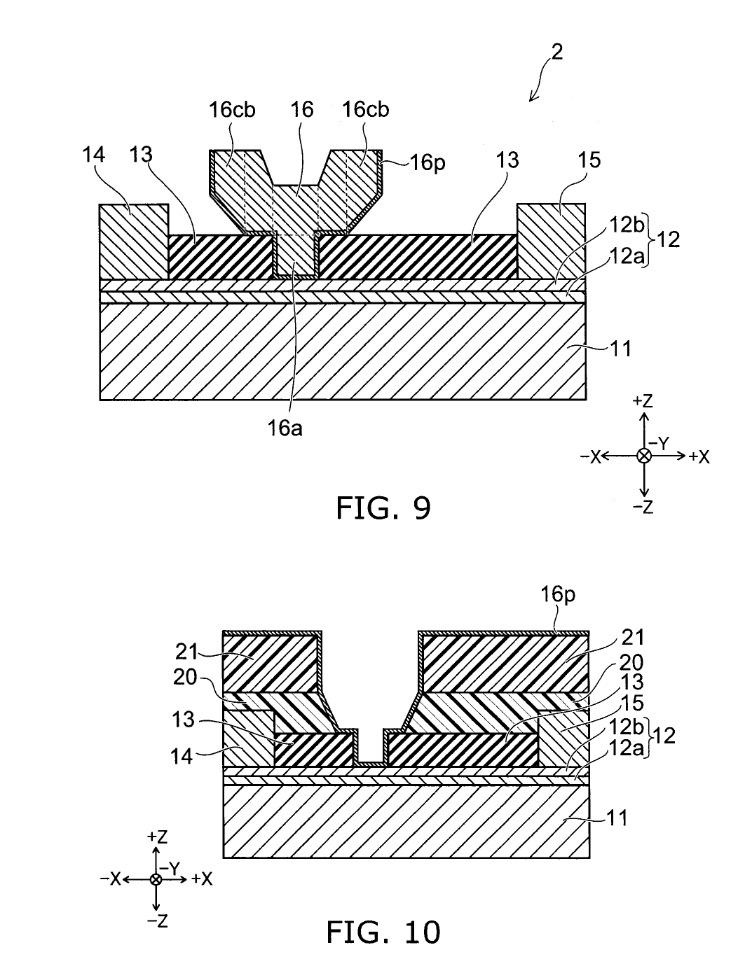

FIG. 9 is a cross-sectional view illustrating a semiconductor device according to the second embodiment.

As shown in FIG. 9, the gate electrode 16 of a semiconductor device 2 according to the embodiment includes a metal film 16p.

The metal film 16p is provided in portions of the gate electrode 16 in contact with the AlGaN layer 12b and in contact with the upper face of the insulating layer 13. The metal film 16p may be provided on the side surface of the penetrating portion 16a of the gate electrode 16, and may be provided on the lower face and the side face of the extending portion 16cb. The metal film 16p contains, for example, platinum (Pt). The gate electrode 16 also includes a nickel (Ni) film formed on a platinum (Pt) film and a gold (Au) film formed on the nickel (Ni) film. Since the metal film 16p contains platinum (Pt), the metal film 16p forms a Schottky junction with the AlGaN layer 12b.

Next, a manufacturing method of the semiconductor device 2 is described according to the embodiment.

FIG. 10 is a schematic cross-sectional view illustrating a manufacturing process of the semiconductor device according to the second embodiment.

First, similarly to the first embodiment described above, the processes shown in FIGS. 2A to 3B are performed. A description of these processes is omitted.

Next, as shown in FIG. 10, a metal material, for example, platinum (Pt) is evaporated on the AlGaN layer 12b exposed at the bottom of the opening 13a, on the side surface of the insulating layer 13 in the opening 13a, on the side surface of the photoresist film 20 in the opening 20a, on the side surface of the photoresist film 21 in the opening 21a, and on the upper surface of the photoresist film 21, and thereby the metal film 16p is formed thereon.

Next, similarly to the first embodiment described above, the process shown in FIG. 3C is performed. Portions on the upper surface of the photoresist film 21 of the metal film 16p, the nickel (Ni) film, and the gold (Au) film are removed together with the photoresist film 20 and the photoresist film 21.

Thus, the semiconductor device 2 is manufactured as shown in FIG. 9.

Next, effects of the embodiment are described.

In the semiconductor device 2 of the embodiment, the metal film 16p is formed in a portion in contact with the AlGaN layer 12b of the gate electrode 16. Also when the metal film 16p is a platinum (Pt) film containing platinum (Pt), the metal film 16p forms a Schottky junction with the AlGaN layer 12b. The platinum (Pt) film has smaller adhesion strength to the AlGaN layer 12b than a nickel (Ni) film. However, since the gate field plate length is 0.1 micrometers (μm) or more, the adhesion to the insulating layer 13 is large, and the Schottky junction between the platinum (Pt) film and the AlGaN layer 12b can be maintained. If the gate field plate length is less than 0.1 micrometers (μm), the adhesion is small and it is difficult to maintain the Schottky junction.

The semiconductor device 2 using a Schottky junction of a platinum (Pt) film and the AlGaN layer 12b exhibits higher frequency characteristics in a frequency range of 17 GHz or less or 14 GHz or less than those using a Schottky junction of a nickel (Ni) film and the AlGaN layer 12b. Therefore, using the platinum film may improve the frequency characteristics of the semiconductor device 2.

Although a structure in which a nickel (Ni) film is formed on the metal film 16p and a gold (Au) film is formed on the nickel (Ni) film is used as the gate electrode 16 in the semiconductor device 2, the gate electrode 16 is not limited thereto. Alternatively, a gold (Au) film may be directly formed on the metal film 16p.

The embodiments described above can provide a semiconductor device having improved electrical characteristics and a method for manufacturing the same.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a semiconductor layer including an GaN layer and a AlGaN layer provided on the GaN layer;
a source electrode provided on the semiconductor layer;
a drain electrode provided on the semiconductor layer;
an insulating layer provided on the semiconductor layer between the source electrode and the drain electrode; and
a gate electrode including a penetrating portion and a gate field plate, the penetrating portion being in contact with the semiconductor layer through the insulating layer and containing platinum in contact with the semiconductor layer, the gate field plate being in contact with an upper face of the insulating layer with a contact length of not less than 0.1 micrometers and not more than 0.3 micrometers and containing platinum in contact with the upper surface.

2. The device according to claim 1, wherein
the gate electrode includes an extending portion extending from the gate field plate; and
lower face of the extending portions is away from the upper face of the insulating layer.

3. The device according to claim 2, wherein a length of the extending portion extending to the source electrode side is shorter than a length of the extending portion extending to the drain electrode side.

4. The device according to claim 2, wherein a distance between the extending portion and the upper face of the insulating layer increases with distance from the gate field plate.

5. The device according to claim 1, wherein the semiconductor layer is provided on a substrate containing at least one of silicon carbide (SiC) and silicon (Si).

6. The device according to claim 1, wherein the insulating layer contains at least one of silicon nitride (SiN) and silicon oxide (SiO₂).

7. The device according to claim 1, wherein a lower face width of the penetrating portion in contact with the semiconductor layer is not less than 0.1 μm and not more than 0.5 μm.

8. The device according to claim 1, wherein the gate electrode has a stacked structure including gold on platinum.

9. The device according to claim 1, wherein the gate electrode has a stacked structure including platinum (Pt), nickel (Ni), and gold (Au).

10. A method for manufacturing a semiconductor device comprising:
forming an insulating layer on a semiconductor layer provided on a substrate and forming a photoresist pattern including an opening on the insulating layer;
forming an opening in the insulating layer using the photoresist pattern as a mask;
heating the photoresist pattern; and
etching the photoresist pattern.

11. The method according to claim 10, wherein the substrate contains one of silicon carbide (SiC) and silicon (Si).

12. The method according to claim 10, wherein the semiconductor layer includes a GaN layer and an AlGaN layer formed on the GaN layer.

13. The method according to claim 10, wherein the insulating layer contains at least one of silicon nitride and silicon oxide.

14. The method according to claim 10, wherein the photoresist pattern is formed so that an inner diameter of the opening is largest at an upper face and decreases downward.

15. The method according to claim 10, wherein the etching is performed so that an upper face of an insulating layer is exposed at a bottom of the opening of the photoresist pattern.

16. The method according to claim 10, further comprising:
forming a source electrode and a drain electrode on the semiconductor layer; and
burying a metal film in the opening of the insulating layer after etching the photoresist pattern.

17. The method according to claim 16, wherein a metal film containing platinum is formed in the opening.

18. The method according to claim 16, wherein a metal film containing platinum is formed in the opening and gold is stacked on the metal film.

19. The method according to claim 16, wherein a metal film containing platinum is formed in the opening and nickel and gold are sequentially stacked on the metal film.
